(19) United States
(12) Patent Application Publication
(10) Pub. No.: US 2013/0121099 A1
(43) Pub. Date: May 16, 2013

(54) AMPLIFIER CIRCUIT AND SEMICONDUCTOR MEMORY DEVICE

(71) Applicant: Hyung-Sik WON, Gyeonggi-do (KR)

(72) Inventor: Hyung-Sik WON, Gyeonggi-do (KR)

(21) Appl. No.: 13/608,535

(22) Filed: Sep. 10, 2012

(30) Foreign Application Priority Data
Nov. 15, 2011 (KR) 10-2011-0118991

(51) Int. Cl. G11C 7/06; H03F 3/18

(52) U.S. Cl. 365/207; 330/296

(57) ABSTRACT

An amplifier circuit includes an amplification unit and a back-bias voltage providing unit. The amplification unit amplifies input data. The back-bias voltage providing unit provides selectively back-bias voltages of different levels to the amplification unit in an initial operation period of the amplification unit and a period after the initial operation period.

### CROSS-REFERENCE TO RELATED APPLICATIONS

The present application claims priority of Korean Patent Application No. 10-2011-0118991, filed on Nov. 15, 2011, which is incorporated herein by reference in its entirety.

### BACKGROUND

1. Field

Exemplary embodiments of the present invention relate to an amplifier circuit for amplifying input data.

2. Description of the Related Art

Amplifier circuits for amplifying input data are used in various fields including a communication field, a semiconductor field, and the like. For example, a semiconductor memory device such as a DRAM amplifies memory cell data using a bit line sense amplifier. Specifically, if a word line is activated, data of a plurality of memory cells connected to the word line is transferred to bit lines, and a bit line sense amplifier senses and amplifies a difference in voltage between two bit lines contained in a bit line pair.

FIG. 1 is a circuit diagram illustrating a bit line sense amplifier 10, a sense amplifier control unit 20 and a cell array 30 in accordance with a related art.

The bit line sense amplifier 10 illustrated in FIG. 1 senses and amplifies a difference in voltage between a main bit line BL and a sub bit line BLB. The bit line sense amplifier 10 illustrated in FIG. 1 may include two PMOS transistors P1 and P2 and two NMOS transistors N1 and N2. Specifically, if the voltage level of the main bit line BL is relatively higher than that of the sub bit line BLB, the PMOS transistor P1 and the NMOS transistor N2 are turned on, the PMOS transistor P2 and the NMOS transistor N1 are turned off. Therefore, the voltage level of the main bit line BL is amplified to the level of a core voltage VCORE by a pull-up power supply terminal RTO, and the voltage level of the sub bit line BLB is amplified to the level of a ground voltage VSS by a pull-down power supply terminal SB. On the contrary, if the voltage level of the sub bit line BLB is relatively higher than that of the main bit line BL, the voltage level of the sub bit line BLB is amplified to the level of the core voltage VCORE by the pull-up power supply terminal RTO, and the voltage level of the main bit line BL is amplified to the level of the ground voltage VSS by the pull-down power supply terminal SB.

The sense amplifier control unit 20 illustrated in FIG. 1 includes a pull-up control unit 21 and a pull-down control unit 22. The pull-up control unit 21 supplies the core voltage VCORE to the pull-up power supply terminal RTO of the sense amplifier 10 in response to a pull-up amplification activation signal SAP. The pull-down control unit 22 supplies the ground voltage VSS to the pull-down power supply terminal SB of the sense amplifier 10 in response to a pull-down amplification activation signal SAN. Here, the pull-up amplification activation signal SAP and the pull-down amplification activation signal SAN are non-activated to a low logic level in a pre-charge operation, and are activated to a high logic level in an active operation.

The entire operation of the bit line sense amplifier 10 and the sense amplifier control unit 20 will be described with reference to FIG. 1. The bit line pair BL and BLB connected to the bit line sense amplifier 10 is typically pre-charged to a same potential. If word line WL1 is enabled, a cell transistor 31 connected to the word line WL1 is turned on, and data of a capacitor 32 flows in the main bit line BL though a channel of the cell transistor 31 (charge sharing). In this case, the sub bit line BLB maintains the pre-charge voltage level, and only the potential of the main bit line BL is changed through the charge sharing. Meanwhile, in the active operation, the pull-up amplification activation signal SAP and the pull-down amplification activation signal SAN are activated from the low logic level to the high logic level. The pull-up control unit 21 is activated in response to the activated pull-up amplification activation signal SAP so that the core voltage VCORE is supplied to the pull-up voltage power terminal RTO. The pull-down control unit 22 is activated in response to the activated pull-down amplification activation signal SAN so that the ground voltage VSS is supplied to the pull-down power supply terminal SB. The bit line sense amplifier 10 amplifies the difference in voltage between the main bit line BL and the sub bit line BLB using the pull-up power supply terminal RTO adjusted to the level of the core voltage VCORE and the pull-down power supply terminal SB adjusted to the level of the ground voltage VSS.

Ideally, if there is a potential difference between the bit line pair BL and BLB, the bit line sense amplifier 10 should precisely sense and amplify the potential difference. However, practically, the bit line sense amplifier 10 may not sense and amplify the potential difference. A potential difference between the bit line pair BL and BLB, hereinafter, is referred to as ‘dV’) and a potential difference, which may be practically sensed, is referred to as an offset (BLSA offset) voltage of the bit line sense amplifier 10. If it may be not guarantee the potential difference having a voltage being identical to or greater than the offset voltage, the bit line sense amplifier 10 may not ensure an exact sensing operation. The mismatch of the bit line sense amplifier 10 may be one of factors which cause the offset voltage. The PMOS transistor pair P1 and P2 and the NMOS transistor pair N1 and N2 for performing the sensing operation in the bit line sense amplifier 10, should be identically manufactured to have the same operational characteristics. However, practically, the structural layout of the PMOS and NMOS transistor pairs is not exactly symmetrically designed. Although the layout is symmetrically designed, the patterns of the PMOS and NMOS transistor pairs are not identically formed. In addition, contacts between the PMOS and NMOS transistor pairs are not identically defined. For these reasons, the mismatch of the bit line sense amplifier 10 always may exist.

FIG. 2 is a graph illustrating a degree of threshold voltage mismatch of the NMOS transistor pair N1 and N2 or PMOS transistor pair P1 and P2 constituting the bit line sense amplifier 10 illustrated in FIG. 1. As illustrated in FIG. 2, the degree of the threshold voltage of the NMOS transistor pair N1 and N2 becomes larger as the threshold voltage V_{T} of the NMOS transistors N1 and N2 becomes higher. Similarly, the threshold voltage of the PMOS transistor pair P1 and P2 becomes larger as the threshold voltage V_{T} of the PMOS transistors P1 and P2 becomes higher.

If the threshold voltage of the NMOS transistor pair N1 and N2 or the threshold voltage of the PMOS transistor pair P1 and P2 is large, the bit line sense amplifier 10 may not ensure an exact sensing operation.

### SUMMARY

An embodiment of the present invention is directed to an amplifier circuit that receives back-bias voltages of different levels, depending operation periods of an amplification unit.

In accordance with an embodiment of the present invention, an amplifier circuit includes an amplification unit configured to amplify input data; and a back-bias voltage providing unit configured to provide back-bias voltages of different levels to the amplification unit in an initial operation period of the amplification unit and a period after the initial operation period.

In accordance with another embodiment of the present invention, a semiconductor memory device includes a bit line configured to be connected to a memory cell; a sense amplifier configured to amplify data transferred to the bit line; a sense amplifier control unit configured to supply a pull-up voltage and a pull-down voltage to the sense amplifier in response to an amplification activation signal; and a back-bias voltage providing unit configured to provide back-bias voltages of different levels to the sense amplifier in an initial activation period of the amplification activation signal and a period after the initial activation period.

### BRIEF DESCRIPTION OF THE DRAWINGS

FIG. 1 is a circuit diagram illustrating a bit line sense amplifier, a sense amplifier control unit and a cell array unit in accordance with a related art.

FIG. 2 is a graph illustrating a degree of threshold voltage mismatch of transistor pairs constituting the sense amplifier illustrated in FIG. 1.

FIG. 3 is a circuit diagram illustrating a semiconductor memory device in accordance with an embodiment of the present invention.

FIG. 4 is a timing diagram illustrating the semiconductor memory device illustrated in FIG. 3.

FIG. 5 is a circuit diagram illustrating a semiconductor memory device in accordance with another embodiment of the present invention.

FIG. 6 is a circuit diagram illustrating a semiconductor memory device in accordance with still another embodiment of the present invention.

FIG. 7 is a circuit diagram illustrating a semiconductor memory device in accordance with still another embodiment of the present invention.

FIG. 8 is a circuit diagram illustrating a semiconductor memory device in accordance with still another embodiment of the present invention.

FIG. 9 is a circuit diagram illustrating a semiconductor memory device in accordance with still another embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

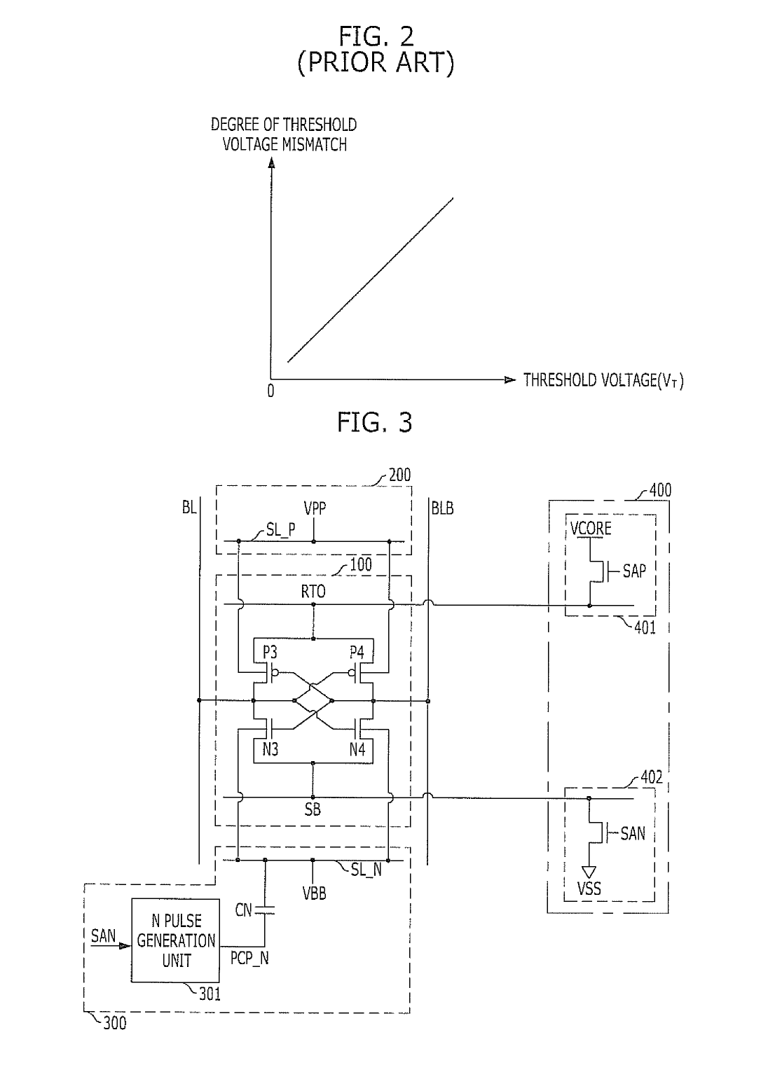

FIG. 3 is a circuit diagram illustrating a semiconductor memory device in accordance with an embodiment of the present invention.

The semiconductor memory device may include main/sub bit lines BL and BLB, a sense amplifier 100, a sense amplifier control unit 400, a first back-bias voltage providing unit 200 and a second back-bias voltage providing unit 300.

The main/sub bit lines BL and BLB are connected to a memory cell (not shown). Data read from the memory cell (not shown) is transferred to the main/sub bit lines BL and BLB.

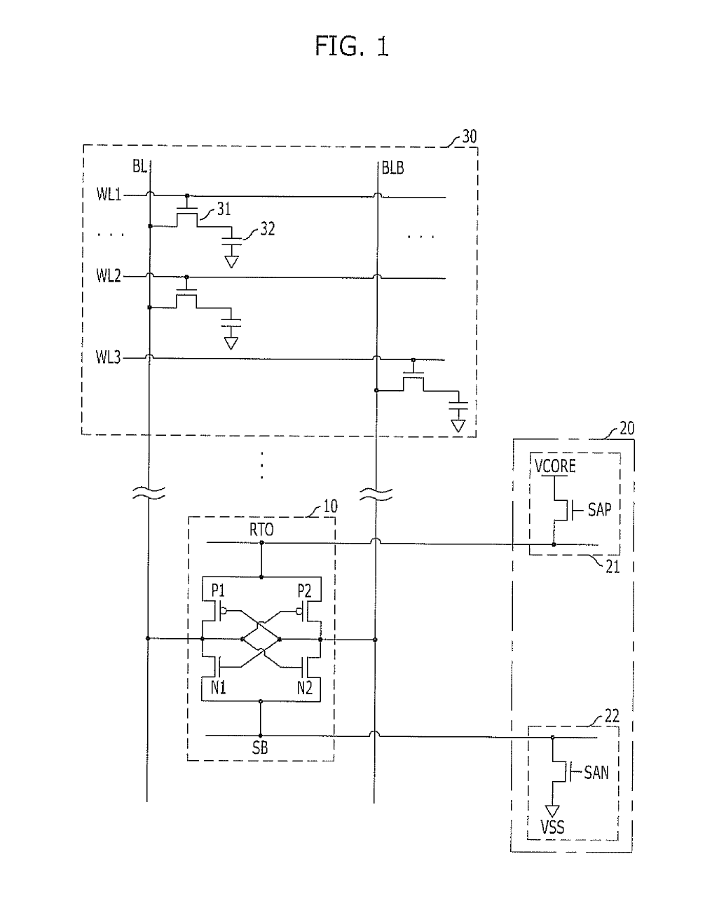

The sense amplifier 100 senses a difference in voltage between the main/sub bit lines BL and BLB, and amplifies the sensed difference. The sense amplifier 100 may include a plurality of PMOS transistors P3 and P4 and a plurality of NMOS transistors N3 and N4. The configuration and principle of the sense amplifier 100 are similar to those of the related art bit line sense amplifier 10 illustrated in FIG. 1, and therefore, its detailed description will be omitted for the sake of convenience.

The sense amplifier control unit 400 supplies a pull-up voltage and a pull-down voltage to the sense amplifier 100 in response to amplification activation signals SAP and SAN. Specifically, the sense amplifier control unit 400 may include a pull-up control unit 401 and a pull-down control unit 402. The pull-up control unit 401 supplies a pull-up voltage to the sense amplifier 100 in response to the pull-up amplification activation signal SAP. In FIG. 3, a case where the pull-up voltage is a core voltage VCORE and the pull-up control unit 401 is configured as an NMOS transistor has been described as an example for the illustrative purpose. Here, the pull-up amplification activation signal SAP is non-activated as a low logic level in a pre-charge operation, and is activated as a high logic level in an active operation. Meanwhile, the pull-up control unit 401 may be designed as a PMOS transistor in place of the NMOS transistor. In this case, the pull-up amplification activation signal SAP may be designed to be non-activated as the high logic level in the pre-charge operation and to be activated as the low logic level in the active operation.

The pull-down control unit 402 supplies a pull-down voltage to the sense amplifier 100 in response to the pull-down amplification activation signal SAN. In FIG. 3, a case where the pull-down voltage is a ground voltage VSS and the pull-down control unit 402 is configured as an NMOS transistor has been described as an example for the illustrative purpose. Here, the pull-down amplification activation signal SAN is non-activated as the low logic level in the pre-charge operation, and is activated as the high logic level in the active operation.

The first back-bias voltage providing unit 200 provides a first back-bias voltage VPP to the bulk of the PMOS transistor pair P3 and P4 constituting the sense amplifier 100. Specifically, the first back-bias voltage providing unit 200 provides the first back-bias voltage VPP to the bulk of the PMOS transistor pair P3 and P4 of the sense amplifier 100 during an activation period of the pull-up amplifier activation signal SAP (i.e., during a sensing operation period of the sense amplifier 100). Here, the first back-bias voltage VPP is a high voltage, and is preferably a voltage of a higher level than that of a power voltage VDD. In FIG. 3, a case where the first back-bias voltage providing unit 200 is configured as a first back-bias voltage supply terminal SL_P for receiving the back-bias voltage VPP has been described as an example for the illustrative purpose. The first back-bias voltage supply terminal SL_P receives the first back-bias voltage VPP and provides the received first back-bias voltage VPP to the bulk of the PMOS transistor pair P3 and P4 of the sense amplifier 100.

The second back-bias voltage providing unit 300 provides back-bias voltages of different levels to the bulk of the NMOS transistor pair N3 and N4 constituting the sense amplifier 100 according to sensing periods of the sense amplifier 100 (e.g., a sensing initial period and a period after the initial sensing period). Specifically, the second back-bias voltage providing unit 300 selectively provides the back-bias voltages of different levels to the bulk of the NMOS transistor pair N3 and N4 according to the initial sensing period and the period after the initial sensing period, e.g., an initial activation period (hereinafter, referred to as ‘T1’) of the pull-down amplification activation signal SAN and a period (hereinafter, referred to as ‘T2’) after the initial activation period. That is, the second back-bias voltage providing unit 300 selectively provides a back-bias voltage of third level to the bulk of the NMOS transistor pair N3 and N4 in the period T1, and provides a back-bias voltage of fourth level to the bulk of the NMOS transistor pair N3 and N4 in the period T2. Here, the back-bias voltage VBB of the fourth level may be designed to be a voltage of a level identical to or lower than that of the ground voltage VSS, and the back-bias voltage of the third level is a voltage may be designed to be a voltage of a level higher than that of the back-bias voltage VBB of the fourth level. In FIG. 3, a case where one back-bias voltage VBB is amplified as a higher level and provided to the bulk of the NMOS transistor pair N3 and N4 of the sense amplifier 100 has been described as an example for the illustrative purpose. That is, the second back-bias voltage providing unit 300 provides the back-bias voltage VBB to the bulk of the NMOS transistor pair N3 and N4 of the sense amplifier 100. Then, the second back-bias voltage providing unit 300 amplifies the back-bias voltage VBB as a higher level in the period T1 and provides the back-bias voltage VBB amplified as the higher level to the bulk of the NMOS transistor pair N3 and N4.

Specifically, the second back-bias voltage providing unit 300 may include a second back-bias supply terminal SL_N to which the back-bias voltage VBB is supplied and a capacitor CN. The second back-bias voltage supply terminal SL_N receives the back-bias voltage VBB and provides the received back-bias voltage VBB to the NMOS transistor pair N3 and N4. One end of the capacitor CN is connected to the second back-bias voltage supply terminal SL_N, and the other end of the capacitor CN receives an N pulse signal PCP_N. Here, the N pulse signal PCP_N is a signal that is activated as the high logic level in the period T1 and non-activated as the low logic level in the period T2. The N pulse signal PCP_N is generated in an N pulse generation unit 301. In FIG. 3, a case where the N pulse generation unit 301 generates the N pulse signal PCP_N using the pull-down amplification activation signal SAN has been described as an example. If the N pulse signal PCP_N activated as the high logic level in the period T1 is inputted to the one end of the capacitor CN, the voltage between both the ends of the capacitor CN may be necessarily maintained constant, and hence the voltage level at the second back-bias voltage supply terminal SL_N rises corresponding to a variation in voltage level of the N pulse signal CPC_N in the period T1. Therefore, the second back-bias voltage providing unit 300 provides the back-bias voltage VBB to the bulk of the NMOS transistor pair N3 and N4 of the sense amplifier 100 in period T2. Then, the second back-bias voltage providing unit 300 amplifies the back-bias voltage VBB as a higher level and provides the back-bias voltage VBB amplified as the higher level to the bulk of the NMOS transistor pair N3 and N4 in period T1.

Meanwhile, in FIG. 3, a case where the second back-bias voltage providing unit 300 amplifies the back-bias voltage VBB as a higher level and provides the back-bias voltage VBB amplified as the higher level to the bulk of the NMOS transistor pair N3 and N4 in period T1 has been described for convenience of illustration. However, the second back-bias voltage providing unit 300 may be designed to provide two back-bias voltages of different levels to the sense amplifier 100 in the respective periods T1 and T2.

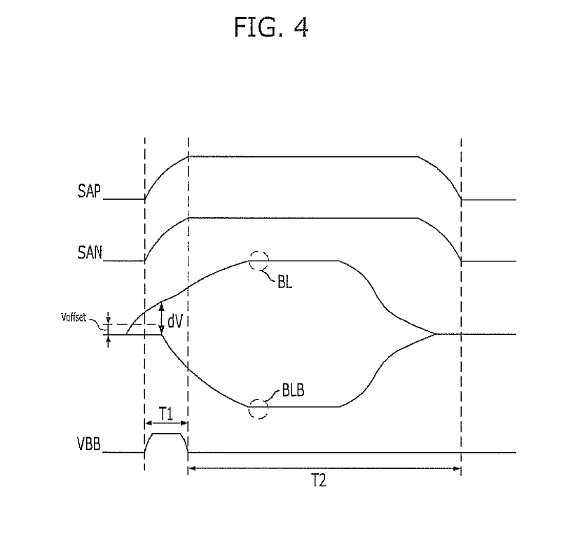

FIG. 4 is a timing diagram illustrating the semiconductor memory device illustrated in FIG. 3. The entire operation of the semiconductor memory device illustrated in FIG. 3 will be described with reference to FIG. 4.

In the active operation, the pull-up amplification activation signal SAP and the pull-down amplification activation signal SAN are activated as the high logic level. The pull-up control unit 401 transfers the core voltage VCORE to a pull-up power supply terminal RTO in response to the pull-up amplification activation signal SAP activated as the high logic level. The pull-down control unit 402 transfers the ground voltage VSS to a pull-down power supply terminal SB in response to the pull-down amplification activation signal SAN activated as the high logic level.

In this case, the N pulse generation unit 301 generates the N-pulse signal PCP_N activated as the high logic level using the pull-down amplification activation signal SAN during the period T1. If the back-bias voltage VBB is supplied to the second back-bias voltage supply terminal SL_N and the N pulse signal PCP_N is inputted to the capacitor CN connected to the second back-bias voltage supply terminal SL_N, the voltage level at the second back-bias voltage supply terminal SL_N in the period T1 is amplified as the high logic level. That is, the back-bias voltage VBB amplified as the high logic level is provided to the bulk of the NMOS transistor pair N3 and N4 of the sense amplifier 100 during the period T1. Therefore, the threshold voltage of each of the NMOS transistors N3 and N4 in period T1 is lower than that when the back-bias voltage VBB of the low logic level is provided to the bulk of the NMOS transistor pair N3 and N4. Accordingly, the level of the threshold voltage of each of the NMOS transistors N3 and N4 in the initial sensing period of the sense amplifier 100, i.e., the period T1 is lower than that in the period T2, and the degree of threshold voltage mismatch of the NMOS transistor pair N3 and N4 is decreased as illustrated in Table 1.

TABLE 1
[Threshold voltage variations of NMOS transistor pair
N3 and N4 in periods T1 and T2]

| | | | | The |
|---|---|---|---|---|
| | | | | diff- |
| | Level of | | | erence |
| | back-bias | Level of | Level of | of |
| | voltage | threshold | threshold | threshold |
| | (VBB) | voltage of N3 | voltage of N4 | voltages |
| Period | −0.1 V | 0.6 V | 0.4 V | 0.2 V |
| T1 | | | | |
| Period | 0.0 V | 0.6 V*0.8 = 0.48 V | 0.4V*0.8 = 0.32 V | 0.16 V |
| T2 | | | | |

In Table 1, it is assumed that if the level of the back-bias voltage VBB provided to the bulk of the NMOS transistor pair N3 and N4 is increased by 0.1V, the level of the threshold voltage of each of the NMOS transistors N3 and N4 is lowered to 80% of the level of the previous threshold voltage. The difference between the threshold voltages of the NMOS transistor pair N3 and N4 in the period T2 is 0.2V, but the difference between the threshold voltages of the NMOS transistor pair N3 and N4 in the period T1 is 0.16V. That is, it can be seen that the threshold voltage of each of the NMOS transistor pair N3 and N4 is lowered in the period T1 in which the level of the back-bias voltage VBB provided to the bulk of the NMOS transistor pair N3 and N4 is increased.

If the threshold voltage of each of the NMOS transistors N3 and N4 is decreased, an offset voltage V_{OFFSET} is decreased. If the offset voltage V_{OFFSET} is decreased, the voltage difference (dV) between the bit line pair BL and BLB is more stably secured to have a value of the offset voltage V_{OFFSET} or more, so that it may be possible to ensure an exact sensing operation of the sense amplifier 100.

The sense amplifier 100 performs an amplification operation by sensing the difference (dV) in potential between the bit line pair BL and BLB. For example, if it is assumed that the voltage level of the main bit line BL is relatively higher than that of the sub bit line BLB, the NMOS transistor N4 and the PMOS transistor P3 in the sense amplifier 100 are turned on, and the NMOS transistor N3 and the PMOS transistor P4 in the sense amplifier 100 are turned off. Therefore, the voltage level of the main bit line BL is increased to the level of the core voltage VCORE supplied through the pull-up power supply terminal RTO, and the voltage level of the sub bit line BLB is decreased to the level of the ground voltage VSS supplied through the pull-down power supply terminal SB.

Here, the reason why the back-bias voltage VBB of the higher level is provided to the bulk of the NMOS transistor pair N3 and N4 of the sense amplifier 100 only in the initial sensing period (e.g., the period T1) of the sense amplifier 100 is that if a sensing margin is secured in the initial sensing period, the amplification operation can be stably performed. If the back-bias voltage VBB of the high logic level is provided to the bulk of the NMOS transistor pair N3 and N4 even after the initial sensing period, the threshold voltage of each of the NMOS transistors N3 and N4 is continuously maintained as a low-level state, and therefore, leakage current is continuously generated during the operation period of the sense amplifier 100. In order to prevent the leakage current, the back-bias voltage VBB of the higher level is provided to the sense amplifier 100 only in the initial sensing period.

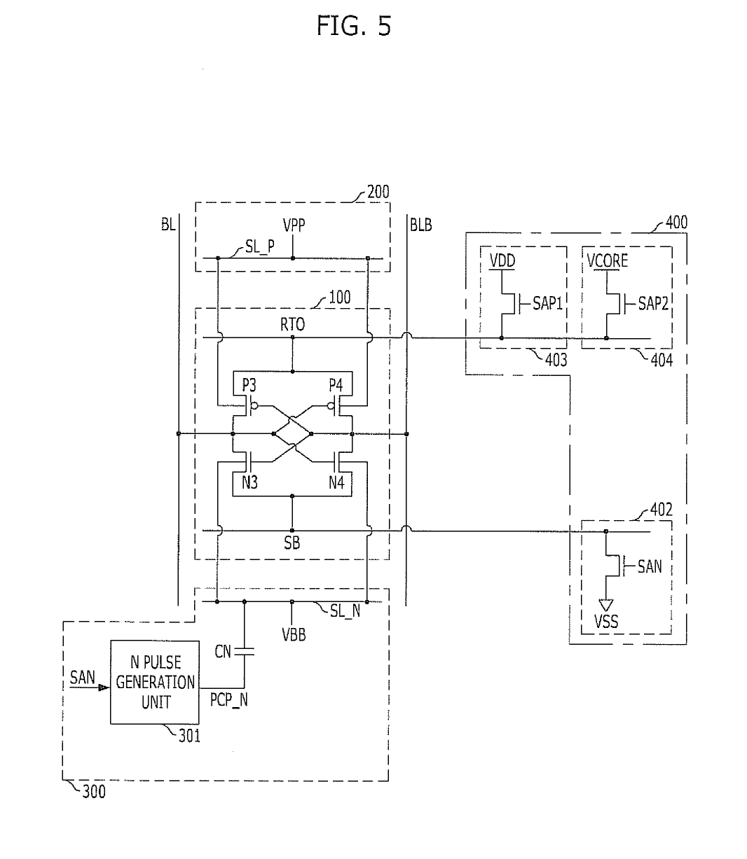

Meanwhile, the semiconductor memory device in accordance with the present invention may be applied even when the sense amplifier 100 is designed into an over-driving structure as illustrated in FIG. 5.

When a semiconductor memory device such as a DRAM is driven, a few thousand of sense amplifiers operate at the same time. In this case, the driving time of the sense amplifiers is determined according to whether or not a sufficient amount of current can be supplied so as to drive the sense amplifiers. However, it may be impossible to supply the sufficient amount of current in a moment due to the degradation of an operating voltage, caused by the tendency to use low power in the semiconductor memory device. In order to solve such a concern, the over-driving structure of the sense amplifier is used. In the over-driving structure of the sense amplifier, a voltage (e.g., power voltage VDD) higher than normal power (generally, core voltage VCORE) supplied to the pull-up power supply terminal RTO is instantaneously supplied to the sense amplifier in an initial operating period of the sense amplifier (just after chare sharing between a memory cell and a bit line).

As illustrated in FIG. 5, the semiconductor memory device may include a sense amplifier 100, a sense amplifier control unit 400, a first back-bias voltage providing unit 200 and a second back-bias voltage providing unit 300.

The configuration and principle of the sense amplifier 100 are similar to those of the sense amplifier 100 illustrated in FIG. 3.

The configurations and principles of the first and second back-bias voltage providing units 200 and 300 are similar to those of the first and second back-bias voltage providing units 200 and 300 illustrated in FIG. 3, respectively.

The sense amplifier control unit 400 supplies a pull-up voltage and a pull-down voltage to the sense amplifier 100 in response to amplification activation signals SAP1, SAP2 and SAN. Specifically, the sense amplifier control unit 400 may include a first pull-up control unit 403, a second pull-up control unit 404 and a pull-down control unit 402. The first pull-up control unit 403 supplies a first pull-up voltage to a pull-up power supply terminal RTO of the sense amplifier 100 in response to the first pull-up amplification activation signal SAP1. In FIG. 5, a case where the first pull-up voltage is a power voltage VDD has been described for convenience of illustration. Specifically, the first pull-up control unit 403 may be configured as an NMOS transistor turned on/off in response to the first pull-up amplification activation signal SAP1. Here, the first pull-up amplification activation signal SAP1 is activated as a high logic level in an initial sensing period (e.g., period T1) of the sense amplifier 100, and is non-activated as a low logic level after the initial sensing period. That is, if the first pull-up amplification activation signal SAP1 is activated as the high logic level in the period T1, the first pull-up control unit 403 supplies the power voltage VDD to the pull-up power supply terminal RTO of the sense amplifier 100. Meanwhile, the first pull-up control unit 403 may be designed as the PMOS transistor in place of the NMOS transistor. In this case, the first pull-up amplification activation signal SAP1 may be designed to be activated as the low logic level in the initial sensing period of the sense amplifier 100 and to be non-activated as the high logic level after the initial sensing period.

The second pull-up control unit 404 supplies a second pull-up voltage to the pull-up power supply terminal RTO of the sense amplifier 100 in response to the second pull-up amplification activation signal SAP2. In FIG. 5, a case where the second pull-up voltage is a core voltage VCORE has been described for convenience of illustration. Specifically, the second pull-up control unit 404 may be configured as an NMOS transistor turned on/off in response to the second pull-up amplification activation signal SAP2. Here, the second pull-up amplification activation signal SAP2 is non-activated as the low logic level in the initial sensing period (e.g., the period T1) of the sense amplifier 100, and is activated as the high logic level after the initial sensing period. That is, the second pull-up control unit 404 does not supply the core voltage VCORE to the sense amplifier 100 in response to the second pull-up amplification activation signal SAP2 non-activated as the low logic level in the initial sensing period (e.g., the period T1), but supplies the core voltage VCORE to the pull-up power supply terminal RTO of the sense amplifier 100 in response to the second pull-up amplification activation signal SAP2 activated as the high logic level after the initial sensing period. Meanwhile, the second pull-up control unit 404 may be designed as the PMOS transistor in place of the NMOS transistor. In this case, the second pull-up amplification activation signal SAP2 may be designed to be non-activated as the high logic level in the initial sensing period and to be activated as the low logic level after the initial sensing period.

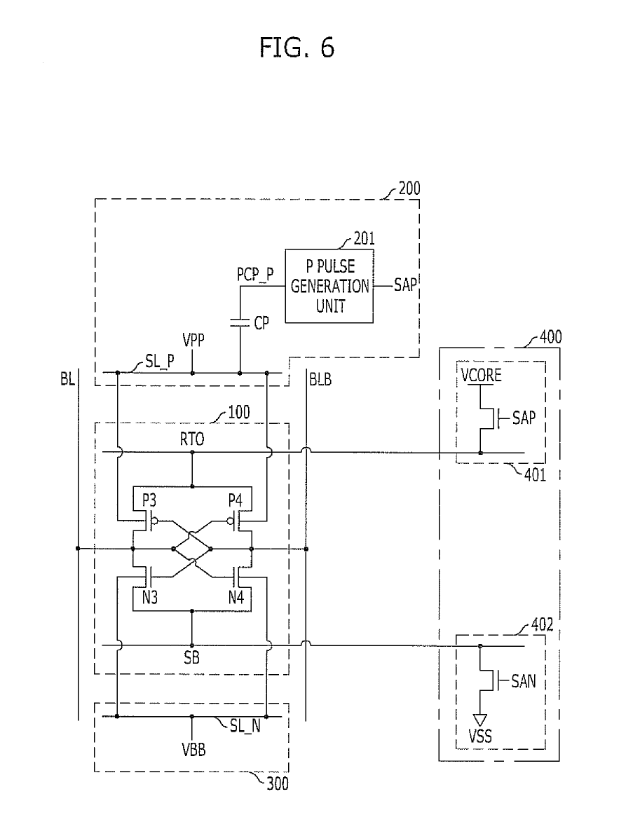

FIG. 6 is a circuit diagram illustrating a semiconductor memory device in accordance with still another embodiment of the present invention. The semiconductor memory device may include a sense amplifier 100, a first back-bias voltage providing unit 200, a second back-bias voltage providing unit 300 and a sense amplifier control unit 400.

The semiconductor memory device illustrated in FIG. 6 provides back-bias voltages of different levels to PMOS transistor pair P3 and P4 of the sense amplifier 100 according to the sensing periods (e.g., an initial sensing period and a period after the initial sensing period) of the sense amplifier 100. However, the semiconductor memory device illustrated in FIG. 3 provides back-bias voltages of different level to the bulk of the NMOS transistor pair N3 and N4 of the sense amplifier 100 according to the sensing periods (e.g., an initial sensing period and a period after the initial sensing period) of the sense amplifier 100.

The configuration and principle of the sense amplifier 100 are similar to those of the sense amplifier 100 illustrated in FIG. 3.

The configuration and principle of the sense amplifier control unit 400 are similar to those of the sense amplifier control unit 400 illustrated in FIG. 3.

The first back-bias voltage providing unit 200 provides back-bias voltages of different levels to the bulk of the PMOS transistor pair P3 and P4 of the sense amplifier 100 according to the sensing periods (e.g., an initial sensing period and a period after the initial sensing period) of the sense amplifier 100. Specifically, the first back-bias voltage providing unit 200 provides the back-bias voltages of the difference levels to the sense amplifier 100 in the initial sensing period of the sense amplifier 100 and the period after the initial sensing period, i.e., in an initial activation period (e.g. period T1) of a pull-up amplification activation signal SAP and a period (e.g., period T2) after the initial activation period. That is, the first back-bias voltage providing unit 200 provides a back-bias voltage of first level to the bulk of the PMOS transistor pair P3 and P4 of the sense amplifier 100 in the period T1, and provides a back-bias voltage of second level to the bulk of the PMOS transistor pair P3 and P4 in the period T2. Here, the back-bias voltage of the second level may be designed as a voltage of a level identical to or higher than that of the power voltage VDD, and the back-bias voltage of the first level may be designed as a voltage of a level lower than that of the back-bias voltage of the second level. In FIG. 6, a case where one back-bias voltage VPP is amplified as a lower level in the period T1 and provided to the bulk of the PMOS transistor pair P3 and P4 of the sense amplifier 100 has been described for convenience of illustration. That is, the first back-bias voltage providing unit 200 provides the back-bias voltage VPP to the bulk of the PMOS transistor pair P3 and P4 of the sense amplifier 100 in the period 12. Then, the first back-bias voltage providing unit 200 amplifies the back-bias voltage VPP as the lower level in period T1, and provides the back-bias voltage VPP amplified as the lower level to the bulk of the PMOS transistor pair P3 and P4.

Specifically, the first back-bias voltage providing unit 200 may include a first back-bias voltage supply terminal SL_P to which the back-bias voltage VPP is supplied and a capacitor CP. The first back-bias voltage supply terminal SL_P receives the back-bias voltage VPP and provides the receive back-bias voltage VPP to the bulk of the PMOS transistor pair P3 and P4 of the sense amplifier 100. One end of the capacitor CP is connected to the first back-bias voltage supply terminal SL_N, and the other end of the capacitor CP receives a P pulse signal PCP_P. Here, the P pulse signal PCP_P is a signal that is activated as the low logic level in the period T1 and non-activated as the high logic level in the period T2. The P pulse signal PCP_P is generated in a P pulse generation unit 201. In FIG. 6, a case where the P pulse generation unit 201 generates the P pulse signal PCP_P using the pull-up amplification activation signal SAP has been described. If the P pulse signal activated as the low logic level in the period T1 is inputted to the one end of the capacitor CP, the voltage between both the ends of the capacitor CP is necessarily maintained constant, and hence the voltage level at the first back-bias voltage supply terminal SL_P in the period T1 is lowered corresponding to a variation in voltage level of the P pulse signal PCP_P. Therefore, the back-bias voltage VPP of a level lower than that of the back-bias voltage VPP provided to the sense amplifier 100 in the period T2 is provided to the bulk of the PMOS transistor pair P3 and P4 of the sense amplifier 100 in the period T1.

If the level of the back-bias voltage VPP provided to the bulk of the PMOS transistor pair P3 and P4 of the sense amplifier 100 is lowered in the period T1, the threshold voltage of each of the PMOS transistors P3 and P4 is lowered in the period T1. If the threshold voltage of each of the PMOS transistors P3 and P4 is lowered, the degree of threshold voltage mismatch of the PMOS transistor pair P3 and P4 is decreased. If the degree of threshold voltage mismatch of the PMOS transistor pair P3 and P4 is decreased, an offset voltage V_{OFFSET} is decreased. If the offset voltage V_{OFFSET} is decreased, the difference (dV) in potential between the bit line pair BL and BLB is more stably secured to have a value of the offset voltage V_{OFFSET} or more, so that it may be possible to ensure an exact sensing operation of the sense amplifier 100.

Meanwhile, a case where the first back-bias voltage providing unit 200 amplifies one back-bias voltage VPP as the lower level in the period T1 and provide the amplified back-bias voltage VPP to the bulk of the PMOS transistor pair P3 and P4 of the sense amplifier 100 has been described for convenience of illustration. However, the first back-bias voltage providing unit 200 may be designed to provide back-bias voltages of different levels to the sense amplifier 100 in the respective periods T1 and T2.

The second back-bias providing unit 300 provides a back-bias voltage VBB to the bulk of the NMOS transistor pair N3 and N4 of the sense amplifier 100. Specifically, the second back-bias providing unit 300 provides the back-bias voltage VBB to the bulk of the NMOS transistor pair N3 and N4 during an activation period of the pull-down amplification activation signal SAN (i.e., a sensing operation period of the sense amplifier 100). Here, the back-bias voltage VBB is a low voltage, and is preferably a voltage of which level identical to or lower than the ground voltage VSS. In FIG. 6, a case where the second back-bias voltage providing unit 300 is configured as a second back-bias voltage supply terminal SL_N for receiving the back-bias voltage VBB has been described for convenience of illustration. The second back-bias voltage supply terminal SL_N receives the back-bias voltage VBB and provides the received back-bias voltage VBB to the bulk of the NMOS transistor pair N3 and N4 of the sense amplifier 100.

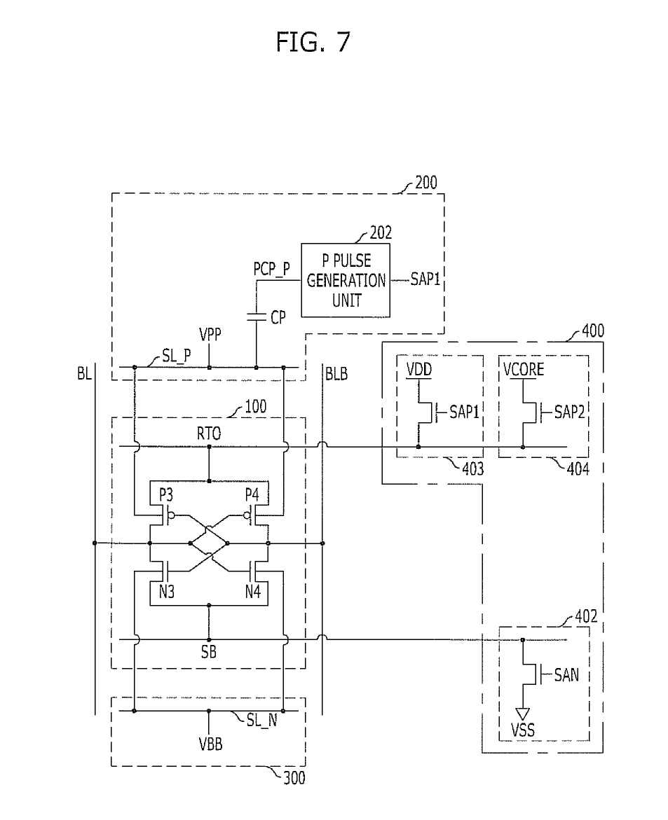

Meanwhile, the semiconductor memory device in accordance with the present invention can be applied even when the sense amplifier 100 is designed into an over-driving structure as illustrated in FIG. 7. The over-driving structure of the sense amplifier 100 has been described with reference to FIG. 5.

The semiconductor memory device illustrated in FIG. 7 may include a sense amplifier 100, a sense amplifier control unit 400, a first back-bias voltage providing unit 200 and a second back-bias voltage providing unit 300.

The configuration and principle of the sense amplifier 100 are similar to those of the sense amplifier 100 illustrated in FIG. 6.

The configuration and principle of the second back-bias voltage providing unit 300 are similar to those of the second back-bias voltage providing unit 300 illustrated in FIG. 6.

The sense amplifier control unit 400 supplies a pull-up voltage and a pull-down voltage to the sense amplifier 100 in response to amplification activation signals SAP1, SAP2 and SAN. Specifically, the sense amplifier control unit 400 may include a first pull-up control unit 403, a second pull-up control unit 404 and a pull-down control unit 402. The configuration and principle of the sense amplifier control unit 400 are similar to those of the sense amplifier control unit 400 illustrated in FIG. 5.

The first back-bias voltage providing unit 200 provides back-bias voltages of different levels to the bulk of the PMOS transistor pair P3 and P4 of the sense amplifier 100 according to the sensing periods (e.g., an initial sensing period and a period after the initial sensing period) of the sense amplifier 100. That is, the first back-bias voltage providing unit 200 provides a back-bias voltage of first level to the bulk of the PMOS transistor pair P3 and P4 of the sense amplifier 100 in the initial sensing period (e.g., period T1) of the sense amplifier 100, and provides a back-bias voltage of the second level to the bulk of the PMOS transistor pair P3 and P4 of the sense amplifier 100 in a period (e.g., period T2) after the initial sensing period. The configuration and principle of the first back-bias voltage providing unit 200 are similar to those of the first back-bias voltage providing unit 200 illustrated in FIG. 6. In FIG. 7, a case where the first back-bias voltage providing unit 200 amplifies one back-bias voltage VPP as a lower level in the period T1 and provides the back-bias voltage VPP amplified as the lower level to the bulk of the PMOS transistor pair P3 and P4 of the sense amplifier 100 has been described for convenience of illustration. That is, the first back-bias voltage providing unit 200 provides the back-bias voltage VPP to the bulk of the PMOS transistor pair P3 and P4 of the sense amplifier 100 in the period T2. Then, the first back-bias voltage providing unit 200 amplifies the back-bias voltage VPP as the lower level in the period T1 and provides the back-bias voltage VPP amplified as the lower level to the bulk of the PMOS transistor pair P3 and P4. Specifically, the first back-bias voltage providing unit 200 may include a first back-bias voltage supply terminal SL_P to which the back-bias voltage VPP is supplied and a capacitor CP. The first back-bias voltage supply terminal SL_P receives the back-bias voltage VPP and provides the receive back-bias voltage VPP to the bulk of the PMOS transistor pair P3 and P4 of the sense amplifier 100. One end of the capacitor CP is connected to the first back-bias voltage supply terminal SL_N, and the other end of the capacitor CP receives a P pulse signal PCP_P. Here, the P pulse signal PCP_P is a signal that is activated as the low logic level in the period T1 and non-activated as the high logic level in the period T2. The P pulse signal PCP_P is generated in a P pulse generation unit 201. In FIG. 7, a case where the P pulse generation unit 201 generates the P pulse signal PCP_P using the first pull-up amplification activation signal SAP1 has been described. If the P pulse signal activated as the low logic level in the period T1 is inputted to the one end of the capacitor CP, the voltage between both the ends of the capacitor CP is necessarily maintained constant, and hence the voltage level at the first back-bias voltage supply terminal SL_P in the period T1 is lowered corresponding to a variation in voltage level of the P pulse signal PCP_P. Therefore, the back-bias voltage VPP of a level lower than that of the back-bias voltage VPP provided to the sense amplifier 100 in the period T2 is provided to the bulk of the PMOS transistor pair P3 and P4 of the sense amplifier 100 in the period T1.

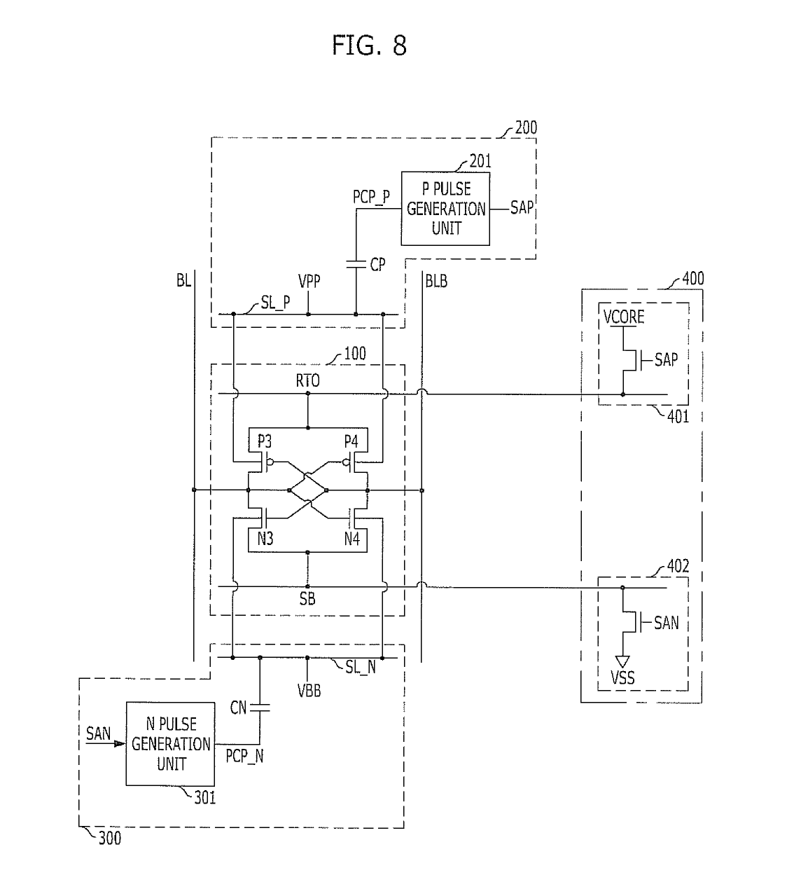

FIG. 8 is a circuit diagram illustrating a semiconductor memory device in accordance with still another embodiment of the present invention. The semiconductor memory device illustrated in FIG. 8 may include a sense amplifier 100, a first back-bias voltage providing unit 200, a second back-bias voltage providing unit 300 and a sense amplification unit 400.

The semiconductor memory device illustrated in FIG. 8 is different from the semiconductor memory device illustrated in FIG. 3 (or FIG. 6) in that back-bias voltages of different levels are provided to the bulk of the NMOS transistor pair N3 and N4 of the sense amplifier 100 according to the sensing periods of the sense amplifier 100 (e.g., an initial sensing period and a period after the initial sensing period), and back-bias voltages of different levels are provided to the bulk of the PMOS transistor pair P3 and P4 of the sense amplifier 100 according to the sensing periods of the sense amplifier 100 (e.g., the initial sensing period and the period after the initial sensing period).

The configuration and principle of the sense amplifier 100 are similar to those of the sense amplifier 100 illustrated in FIG. 3.

The configuration and principle of the sense amplifier control unit 400 are similar to those of the sense amplifier control unit 400 illustrated in FIG. 3.

The first back-bias voltage providing unit 200 provides back-bias voltages of different levels to the bulk of the PMOS transistor pair P3 and P4 of the sense amplifier 100 according to the sensing periods of the sense amplifier 100 (e.g., the initial sensing period and the period after the initial sensing period). The configuration and principle of the first back-bias voltage providing unit 200 are similar to those of the first back-bias voltage providing unit 200 illustrated in FIG. 6.

The second back-bias voltage providing unit 300 provides back-bias voltages of different levels to the bulk of the NMOS transistor pair N3 and N4 of the sense amplifier 100 according to the sensing periods of the sense amplifier 100 (e.g., the initial sensing period and the period after the initial sensing period). The configuration and principle of the second back-bias voltage providing unit 300 are similar to those of the second back-bias voltage providing unit 300 illustrated in FIG. 3.

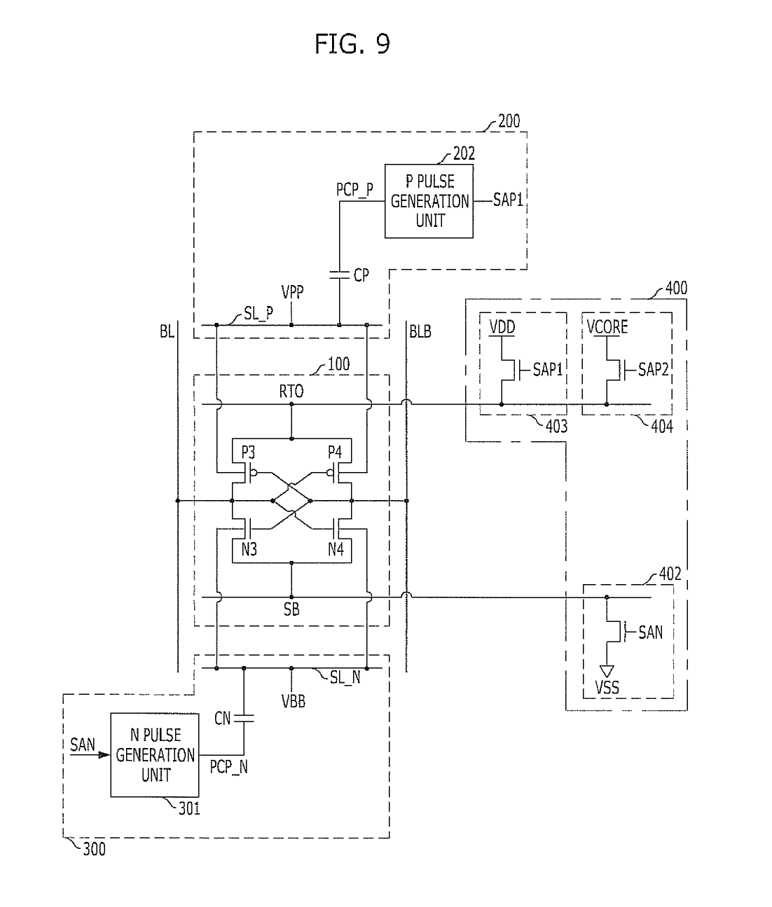

Meanwhile, the semiconductor memory device in accordance with the present invention can be applied even when the sense amplifier 100 is designed into an over-driving structure as illustrated in FIG. 9. The over-driving structure of the sense amplifier 100 has been described with reference to FIG. 5.

The semiconductor memory device illustrated in FIG. 9 may include a sense amplifier 100, a sense amplifier control unit 400, a first back-bias voltage providing unit 200 and a second back-bias voltage providing unit 300.

The configuration and principle of the sense amplifier 100 are similar to those of the sense amplifier 100 illustrated in FIG. 3.

The first back-bias voltage providing unit 200 provides back-bias voltages of different levels to the bulk of the PMOS transistor pair P3 and P4 of the sense amplifier 100 according to the sensing periods of the sense amplifier 100 (e.g., an initial sensing period and a period after the initial sensing period). The configuration and principle of the first back-bias voltage providing unit 200 are similar to those of the first back-bias voltage providing unit 200 illustrated in FIG. 7.

The second back-bias voltage providing unit 300 provides back-bias voltages of different levels to the bulk of the NMOS transistor pair N3 and N4 of the sense amplifier 100 according to the sensing periods of the sense amplifier 100 (e.g., the initial sensing period and the period after the initial sensing period). The configuration and principle of the second back-bias voltage providing unit 300 are similar to those of the second back-bias voltage providing unit 300 illustrated in FIG. 7.

The sense amplifier control unit 400 supplies a pull-up voltage and a pull-down voltage to the sense amplifier 100 in response to amplification activation signals SAP1, SAP2 and SAN. Specifically, the sense amplifier control unit 400 may include a first pull-up control unit 403, a second pull-up control unit 404 and a pull-down control unit 402. The configuration and principle of the sense amplifier control unit 400 are similar to those of the sense amplifier control unit 400 illustrated in FIG. 5.

Although a case where the present invention is applied to the memory device has been described as an example, the present invention can be used to amplify input data not only the semiconductor memory device of the present invention but also various integrated circuit chips.

In accordance with the embodiments of the present invention, the amplifier circuit receives back-bias voltages of different levels according to an initial amplification period of an amplification unit and a period after the initial amplification period, so that it is possible to reduce mismatch of the amplification unit, thereby ensuring a stable amplification operation.

While the present invention has been described with respect to the specific embodiments, it will be apparent to those skilled in the art that various changes and modifications may be made without departing from the spirit and scope of the invention as defined in the following claims.

What is claimed is:

1. An amplifier circuit comprising:
an amplification unit configured to amplify input data; and
a back-bias voltage providing unit configured to provide back-bias voltages of different levels to the amplification unit in an initial operation period of the amplification unit and a period after the initial operation period.

2. The amplifier circuit of claim 1, wherein:
the amplification unit comprises at least one PMOS transistor and at least one NMOS transistor;
the back-bias voltage providing unit provides a back-bias voltage of a first level to the PMOS transistor of the amplification unit in the initial operation period of the amplification unit and provides a back-bias voltage of a second level to the PMOS transistor of the amplification unit in the period after the initial operation period; and
the back-bias voltage providing unit provides a back-bias voltage of a third to the NMOS transistor of the amplification unit in the initial operation period of the amplification unit and provides a back-bias voltage of a fourth level to the NMOS transistor of the amplification unit in the period after the initial operation period.

3. The amplifier circuit of claim 2, wherein the back-bias voltage of the first level is lower than that of the back-bias voltage of the second level, and the back-bias voltage of the third level is higher than that of the back-bias voltage of the fourth level.

4. An amplifier circuit comprising:
an amplification unit configured to comprise at least one PMOS transistor and at least one NMOS transistor, and amplify input data; and
a back-bias voltage providing unit configured to selectively provide back-bias voltages of different levels to the NMOS transistor of the amplification unit in an initial operation period of the amplification unit and a period of the initial operation period.

5. The amplifier circuit of claim 4, wherein a back-bias voltage providing unit configured to selectively provide back-bias voltages of different levels to the PMOS transistor of the amplification unit in an initial operation period of the amplification unit and a period of the initial operation period.

6. A semiconductor memory device, comprising:
a bit line configured to be connected to a memory cell;
a sense amplifier configured to amplify data transferred to the bit line;
a sense amplifier control unit configured to supply a pull-up voltage and a pull-down voltage to the sense amplifier in response to an amplification activation signal; and
a back-bias voltage providing unit configured to provide back-bias voltages of different levels to the sense amplifier in an initial activation period of the amplification activation signal and a period after the initial activation period.

7. The semiconductor memory device of claim 6, wherein:
the sense amplifiers includes at least one PMOS transistor and at least one NMOS transistor; and
the back-bias voltage providing unit provides a back-bias voltage of a first level to the PMOS transistor of the sense amplifier during an activation period of the amplification activation signal, provides a back-bias voltage of a second level to the NMOS transistor of the sense amplifier during the initial activation period of the amplification activation signal, and provides a back-bias voltage of a third level to the NMOS transistor of the sense amplifier during the period of the initial activation period.

8. The semiconductor memory device of claim 7, wherein the back-bias voltage of the third level is higher than that of the back-bias voltage of the fourth level.

9. The semiconductor memory device of claim 7, wherein the back-bias voltage providing unit comprises:
a first back-bias voltage supply terminal to which the back-bias voltage of the first level is supplied;
a second back-bias voltage supply terminal to which the back-bias voltage of the third level is supplied; and
a capacitor having one end connected to the second back-bias voltage supply terminal and the other end receiving a pulse signal activated as a high logic level in the initial activation period of the amplification activation signal.

10. The semiconductor memory device of claim 6, wherein:
the sense amplifiers includes at least one PMOS transistor and at least one NMOS transistor; and
the back-bias voltage providing unit provides a back-bias voltage of a first level to the PMOS transistor of the sense amplifier during the initial activation period of the amplification activation signal, provides a back-bias voltage of a second level to the PMOS transistor of the sense amplifier during the period after the initial activation period, and provides a back-bias voltage of a third level to the NMOS transistor of the sense amplifier during the activation period of the amplification activation signal.

11. The semiconductor memory device of claim 10, wherein the back-bias voltage of the first level is lower than that of the back-bias voltage of the second level.

12. The semiconductor memory device of claim 10, wherein the back-bias voltage providing unit comprises:
a first back-bias voltage supply terminal to which the back-bias voltage of the first level is supplied;
a second back-bias voltage supply terminal to which the back-bias voltage of the third level is supplied; and
a capacitor having one end connected to the first back-bias voltage supply terminal and the other end receiving a pulse signal activated as a low logic level in the initial activation period of the amplification activation signal.

13. The semiconductor memory device of claim 6, wherein:
the sense amplifiers includes at least one PMOS transistor and at least one NMOS transistor; and
the back-bias voltage providing unit provides the back-bias voltage of a first level to the PMOS transistor of the sense amplifier during the initial activation period of the amplification activation signal, provides the back-bias voltage of a second level to the PMOS transistor of the sense amplifier during the period after the initial activation period, provides the back-bias voltage of a third level to the NMOS transistor of the sense amplifier during the initial activation period of the amplification activation signal, and provides the back-bias voltage of a fourth level to the NMOS transistor of the sense amplifier during the period after the initial activation period.

14. The semiconductor memory device of claim 13, wherein the back-bias voltage of the first level lower than that of the back-bias voltage of the second level, and the back-bias voltage of the third level is higher than that of the back-bias voltage of the fourth level.

15. The semiconductor memory device of claim 6, wherein the back-bias voltage providing unit comprises:
a first back-bias voltage supply terminal to which the back-bias voltage of a first level is supplied;
a second back-bias voltage supply terminal to which the back-bias voltage of a third level is supplied;
a first capacitor having one end connected to the first back-bias voltage supply terminal and the other end receiving a first pulse signal activated as a low logic level in the initial activation period of the amplification activation signal; and
a second capacitor having one end connected to the second back-bias voltage supply terminal and the other end receiving a second pulse signal activated as a high logic level in the initial activation period of the amplification activation signal.
